(19) United States
(12) Patent Application Publication
(10) Pub. No.: US 2013/0279974 A1
(43) Pub. Date: Oct. 24, 2013

(54) MOUNTING ASSEMBLY WITH LOCKING MECHANISM

(71) Applicants: HONG FU JIN PRECISION INDUSTRY (ShenZhen ) CO., LTD., (US); HON HAI PRECISION INDUSTRY CO., LTD., New Taipei (TW)

(72) Inventors: ZHAN-YANG LI, Shenzhen (CN); CHONG DUAN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/726,152

(22) Filed: Dec. 23, 2012

(30) Foreign Application Priority Data
Apr. 19, 2012 (CN) 201210116040.3

(51) Int. Cl. H05K 5/02

(52) U.S. Cl. CPC H05K 5/02
USPC 403/327

(57) ABSTRACT

A locking mechanism includes a cap, an elastic member, and a latch member. The cap includes a top portion and defines a receiving hole. The elastic member is received in the receiving hole and located between the top portion and the latch member. The latch member has a first position and a second position relative to the cap. When the latch member is in the first position, a part of the latch member is received in the receiving hole, and another part of the latch member extends through out of the receiving hole. When the latch member is in the second position, the latch member is received in the receiving hole completely. The elastic member is resiliently deformable to move the latch member from the second position to the first position.

### BACKGROUND

1. Technical Field

The present disclosure relates to mounting assemblies, and particularly to a mounting assemblies with a locking mechanism for securing a first component to a second component.

2. Description of Related Art

A conventional method of installing a printed circuit board, such as a motherboard, in a computer is to simply screw the printed circuit board to bosses or other mounting structures suitably mounted on a chassis. However, this printed circuit board installation method increases the time and cost required to construct the computer in addition to adding to the complexity and difficulty of the assembly and disassembly.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting assembly.

FIG. 2 is an assembled view of the mounting assembly of FIG. 1.

FIG. 3 is a cutaway, cross-sectional view of the mounting assembly of FIG. 2, taken along the line III-III.

FIG. 4 is another assembled view of the mounting assembly of FIG. 1.

FIG. 5 is a cutaway, cross-sectional view of the mounting board and the keyboard of FIG. 4, taken along the line V-V.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

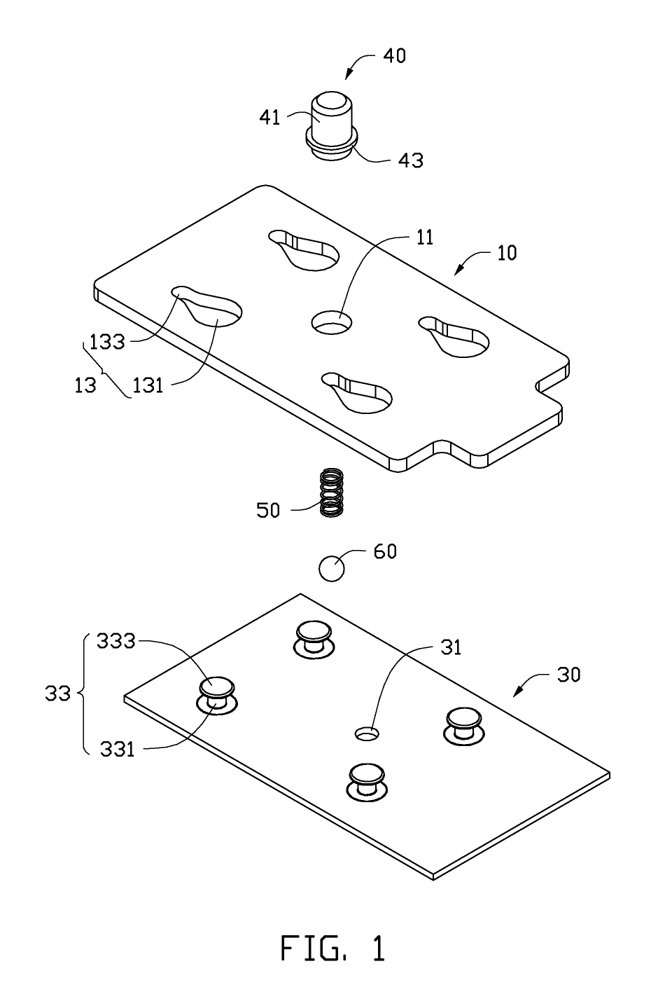

FIG. 1 illustrates a locking mechanism 80 in one embodiment configured to secure a first component 10 to a second component 30. The locking mechanism 80 includes a cap 40, an elastic member 50, and a latch member 60. In one embodiment, the first component 10 is a circuit board, and the second component 30 is a bottom plate of a computer enclosure.

The first component 10 defines a through hole 11 corresponding to the locking mechanism 80. Four positioning holes 13 are defined in the first component 10, surrounding the through hole 11. The four positioning holes 13 are in mirror symmetry. Each of the four positioning holes 13 includes a wide portion 131 and a narrow portion 133 communication with the wide portion 131. A diameter of the wide portion 131 is greater than a diameter of the narrow portion 133.

The second component 30 includes a latch hole 31 corresponding to the locking mechanism 80. Four positioning portions 33 are located on the second component 30. Each of the four positioning portions 33 includes a neck portion 331 and a head portion 333 connected to the neck portion 331. A diameter of the head portion 333 is greater than a diameter of the neck portion 331 and is greater than the diameter of the narrow portion 133.

The cap 40 includes a body 41 and a flange 43 located on outer surface of the body 41. The body 41 has a receiving hole 411 and a top portion 413. In one embodiment, the body 41 is substantially U-shaped. The receiving hole 411 can receive the elastic member 50 and the latch member 60 and includes an end portion 4111 for clamping the latch member 60, to prevent the latch member 60 from disengaging from the receiving hole 411. In one embodiment, the end portion 4111 is substantially arc-shaped.

The elastic member 50 is positioned in the receiving hole 411 of the cap 40. In one embodiment, the elastic member 50 is a compression spring. The latch member includes a touching surface 61. In one embodiment, the touching surface 61 is arc-shaped or a slanted. The latch member 60 is resiliently deformable to be engaged into the receiving hole 411 and clipped by the end portion 4111. In one embodiment, the latch member 60 is a sphere. One end of the elastic member 50 thereby resiliently abuts an outer surface of the latch member 60, and another end of that abuts the top portion 413. The locking mechanism 80 is thereby assembled completely.

To install the locking mechanism 80, a part of the locking mechanism 80 is inserted into the through hole 11 of the first component 10. The flange 43 abuts a top surface of the first component 10 and is secured to the first component 10 by welding way. A part of the latch member 60 extends through out of a bottom surface of the first component 10.

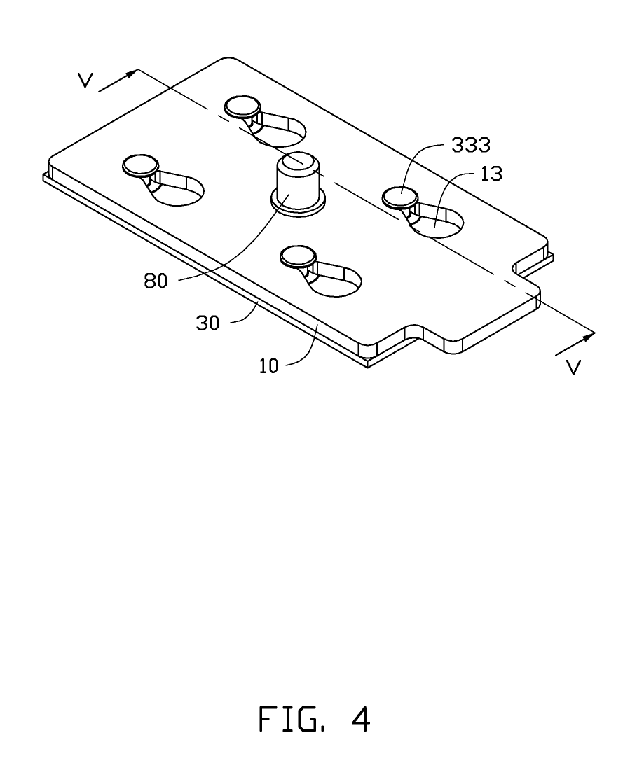

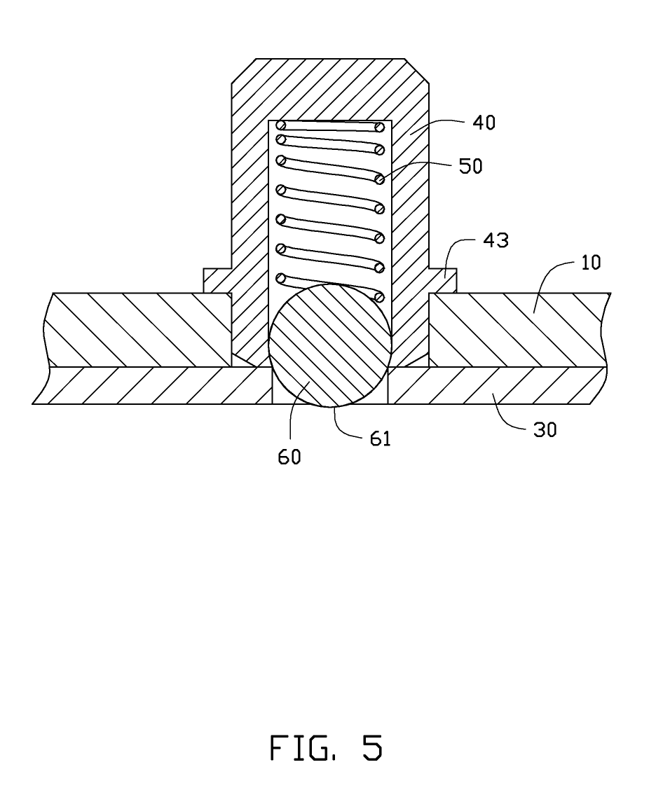

Referring to FIGS. 4 and 5, in assembly of the first component 10 to the second component 30, the first component 10 is placed above the second component 30. The latch member 60 is received into the receiving hole 411. The four positioning portions 33 of the second component 30 are located on the wide portion 131 of the four positioning holes 13 of the first component 10, respectively. The first component 10 is moved along a first direction. The locking mechanism 80 moves towards the latch hole 31 of the second component 30, until the latch member 60 of the locking mechanism 80 is aligned with the latch hole 31. In this position, the elastic member 50 rebounds to push the latch member 60 to engage a part of the latch member 60 into the latch hole 31, and another part of the latch member 60 is received in the receiving hole 411, to prevent the first component 10 from moving in a plane that is parallel to the second component 30. The neck portion 331 of each positioning portion 33 is engaged in the narrow portion 133, and the wide portion 131 abuts the first component 10, to prevent the first component 10 from moving along a direction that is substantially perpendicular to the plane.

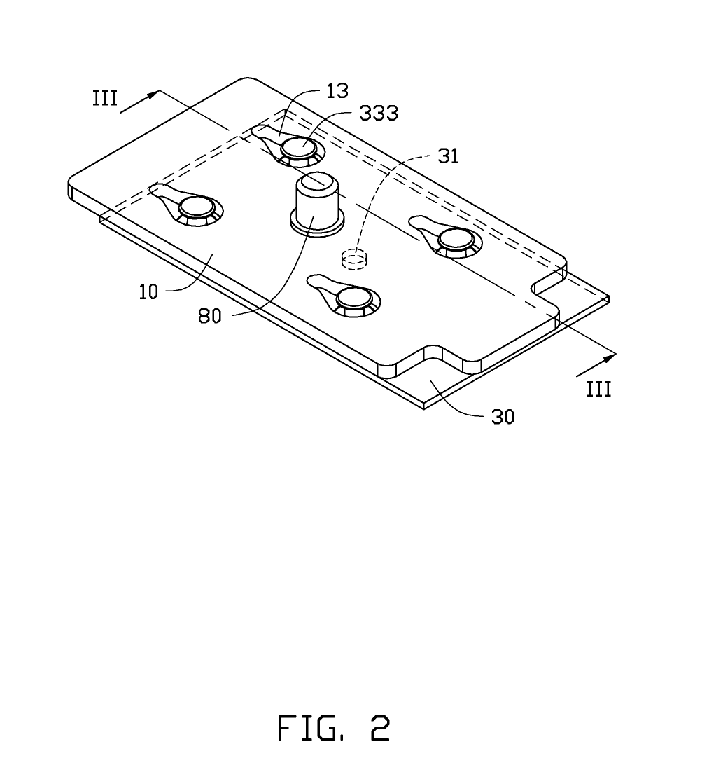

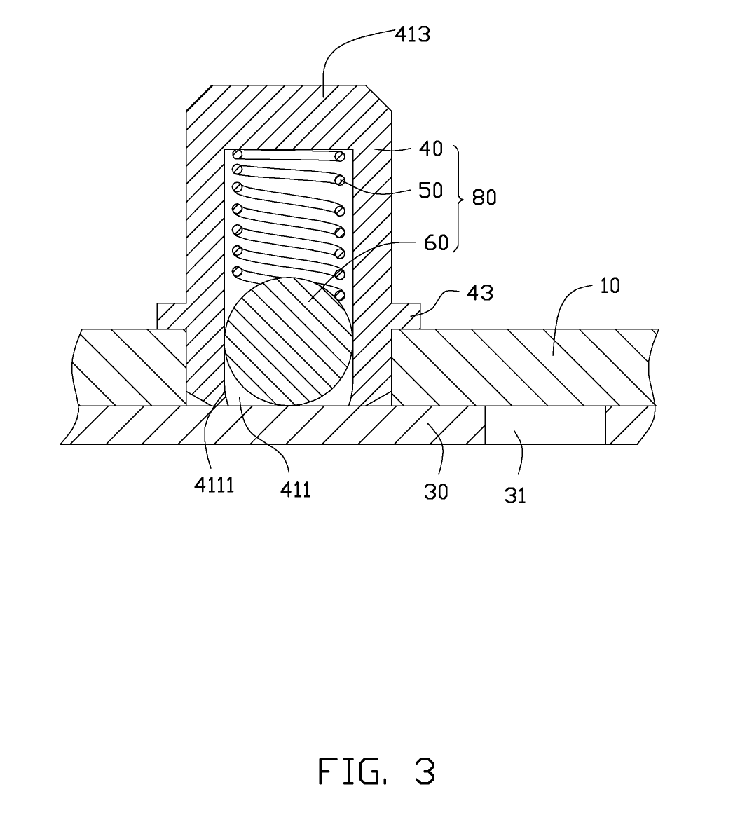

Referring to FIGS. 2 and 3, when detaching the first component 10, the first component 10 is moved towards a second direction opposite to the first direction. An edge of the latch hole 31 of the second component 30 squeezes the touching surface 61 of latch member 60 of the locking mechanism 80, until the latch member 60 retracts into the receiving hole 411 to disengage from the latch hole 31. The neck portion 331 of each positioning portion 33 is disengaged from the narrow portion 133 of each positioning hole 13 to locate in the wide portion 131. The head portion 333 is disengaged from the first component 10. The first component 10 is easily detached from the second component 30.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A locking mechanism comprising:
a cap, the cap comprising a top portion and defining a receiving hole;
an elastic member being received in the receiving hole; and
a latch member,
wherein the elastic member is located between the top portion and the latch member, the latch member has a first position and a second position relative to the cap, when the latch member is in the first position, the latch member protrudes from the cap; when the latch member is in the second position, the latch member is received in the receiving hole completely; and the elastic member is resiliently deformable to move the latch member from the second position to the first position.

2. The locking mechanism of claim 1, wherein a first end of the elastic member abuts the top portion, and a second end of the elastic member opposite to the first end abuts the latch member.

3. The locking mechanism of claim 1, wherein the receiving hole has an end portion, when the latch member is in the first position, the latch member is clipped by the end portion; and when the latch member is in the second position, the latch member is disengaged from the end portion.

4. The locking mechanism of claim 3, wherein the end portion is substantially arc-shaped.

5. The locking mechanism of claim 1, wherein the latch member is sphere.

6. The locking mechanism of claim 1, wherein the cap is substantially U-shaped.

7. The locking mechanism of claim 1, wherein the latch member has a touching surface.

8. The locking mechanism of claim 7, wherein the touching surface is substantially arc-shaped.

9. The locking mechanism of claim 7, wherein the touching surface is slant.

10. A mounting assembly comprising:
a first component;
a second component defining a latch hole; and
a locking mechanism attached to the first component, the locking mechanism comprising:
a cap comprising a top portion and defining a receiving hole;
an elastic member being received in the receiving hole; and
a latch member,
wherein the elastic member is located between the top portion and the latch member, the latch member has a first position and a second position relative to the cap, when the latch member is in the first position, the latch member is engaged into the latch hole, to prevent the first component from moving relative to the second component; when the latch member is in the second position, the latch member is disengaged from the latch hole, to release the first component; and the elastic member is resiliently deformable to move the latch member from the second position to the first position.

11. The mounting assembly of claim 10, wherein a first end of the elastic member abuts the top portion, and a second end opposite to the first end abuts the latch member.

12. The mounting assembly of claim 10, wherein the receiving hole has an end potion, when the latch member is in the first position, the latch member is clipped by the end portion; when the latch member is in the second position, the latch member is disengaged from the end portion.

13. The mounting assembly of claim 12, wherein the end portion is substantially arc-shaped.

14. The mounting assembly of claim 10, wherein the latch member is sphere.

15. The mounting assembly of claim 10, wherein the cap is substantially U-shaped.

16. The mounting assembly of claim 10, wherein the first component defines four positioning holes, four positioning portions are located on the second component, and each of four positioning portions is engaged in each of the four positioning holes.

17. The mounting assembly of claim 16, wherein each of the four positioning holes comprises a narrow portion and a wide portion in communication with the narrow portion, each of the four positioning portions comprises a head portion and a neck portion; when the latch member is in the first position, the neck portion is engaged in the narrow portion, and the head portion abuts the first component; when the latch member is in the second position, the neck portion is located in the wide portion, and the head portion is disengaged from the first component.

18. The mounting assembly of claim 17, wherein a diameter of the narrow portion is smaller than a diameter of the wide portion.

19. The mounting assembly of claim 18, wherein a diameter of the head portion is greater than a diameter of the neck portion, and that it is greater than the narrow portion.
